(19) United States
(12) Patent Application Publication
(10) Pub. No.: US 2018/0047689 A1
(43) Pub. Date: Feb. 15, 2018

(54) ZN DOPED SOLDERS ON CU SURFACE FINISH FOR THIN FLI APPLICATION

(71) Applicant: Intel Corporation, Santa Clara, CA (US)

(72) Inventor: Fay HUA, Fremont, CA (US)

(21) Appl. No.: 15/555,434

(22) PCT Filed: Apr. 1, 2016
(86) PCT No.: PCT/US2016/025652

§ 371 Date: Sep. 1, 2017

Related U.S. Application Data
(60) Provisional application No. 62/142,997, filed on Apr. 3, 2015.

(51) Int. Cl. H01L 23/00

(52) U.S. Cl. CPC H01L 24/13; H01L 24/05; H01L 24/03; H01L 24/11; H01L 2224/08503; H01L 2224/13118; H01L 2924/01327; H01L 2924/206; H01L 2224/05147; H01L 2224/05005; H01L 2224/11849; H01L 2224/0401; H01L 2924/014; H01L 2224/13023; H01L 24/08; H01L 2924/3512

(57) ABSTRACT

Embodiments of the invention include a semiconductor device and methods of forming the semiconductor device. In an embodiment the semiconductor device comprises a semiconductor die with one or more die contacts. Embodiments include a reflown solder bump on one or more of the die contacts. In an embodiment, an intermetallic compound (IMC) barrier layer is formed at the interface between the solder bump and the die contact. In an embodiment, the IMC barrier layer is a CuZn IMC and/or a Cu5Zn8 IMC.

### CROSS-REFERENCE TO RELATED APPLICATIONS

This application claims the benefit of U.S. Provisional Patent Application 62/142,997 filed Apr. 3, 2015, entitled ZN DOPED SOLDERS ON CU SURFACE FINISH FOR THIN FLI APPLICATION, and which is incorporated herein by reference in its entirety for all purposes.

### FIELD OF THE INVENTION

Embodiments generally relate to semiconductor devices. More specifically, embodiments relate to solders used in semiconductor devices.

### BACKGROUND OF THE INVENTION

Current lead-free soldering solutions have several drawbacks. For example, lead-free solders such as tin-copper solders (e.g., Sn with 0.7 weight percent Cu), tin-silver (e.g., Sn with between 2.0 and 3.0 weight percent Ag), and SAC (Sn with 2-4 weight percent Ag and 0.5-1.0 weight percent Cu) result in the formation of intermetallic compounds (IMCs) (e.g., Sn—Cu IMCs) at the interface between the solder joint and copper bump. The thickness of the IMC within the solder joint increases as the duration and the number of the reflows are increased. Additionally, IMC growth may also occur during reliability testing, such as high temperature bakes and thermal cycling. Specifically, in solder joints that have a thickness that is approximately 25 μm or less, the IMC layer may grow to be the entire thickness of the solder joint. The presence of IMCs in a solder joint negatively affects the reliability of a semiconductor device. IMC growth within a solder joint increases the stress in the solder joint and leads to cracking or delamination of the low K interlayer dielectric (ILD), or stacking vias of the device die. The rapid growth of Sn—Cu IMCs also accelerates the consumption of the pad metallurgy on the substrates. In the case of bond on trace (BOT) first level interconnects, the trace on the substrate may be consumed completely during multiple reflows and subsequent reliability testing. As such, device open failures may be produced.

Current solutions to solve the issue of IMC growth at the interface between copper and solder joints have been to use a barrier layer. For example, a nickel plating over the copper pads may minimize the growth of IMCs. However, the use of nickel has significant environmental and health issues. Furthermore, the inclusion of an additional plating operation to provide the barrier layer increases the overall cost of production and reduces throughput.

### BRIEF DESCRIPTION OF THE DRAWINGS

FIG. 1 illustrates the Sn corner of a Sn—Zn—Cu phase diagram.

FIG. 2 is a graphical representation of normalized stress values of various solder systems, according to embodiments of the invention.

FIG. 3A is a pair of cross-sectional micrographs of the interface between a Sn100 solder and a copper surface after a ten minute reflow and a thirty minute reflow.

FIG. 3B is a pair of cross-sectional micrographs of the interface between a Sn solder with 0.2 weight percent Zn and a copper surface after a ten minute reflow and a thirty minute reflow.

FIG. 3C is a pair of cross-sectional micrographs of the interface between a Sn solder with 0.6 weight percent Zn and a copper surface after a ten minute reflow and a thirty minute reflow.

FIG. 3D is a pair of cross-sectional micrographs of the interface between a Sn solder with 2.0 weight percent Zn and a copper surface after a ten minute reflow and a thirty minute reflow.

FIG. 3E is a pair of cross-sectional micrographs of the interface between a Sn solder with 0.7 weight percent Cu and a copper surface after a ten minute reflow and a thirty minute reflow.

FIG. 3F is a micrograph of the interface between a SAC solder with 0.4 weight percent Zn and a copper surface.

FIG. 3G is a micrograph of the interface between a SAC solder with 1.5 weight percent Zn and a copper surface.

FIG. 4A is a graph of the thickness of intermetallic compounds formed in a variety of solders over various reflow times.

FIG. 4B is a graph of the minimum concentration of Zn needed in a solder with respect to the height of the solder for various thicknesses of Cu—Zn IMC formation.

FIG. 5A is a cross-sectional illustration of a semiconductor die with an unreflown solder bump placed on each die contact, according to an embodiment of the invention.

FIG. 5B is a cross-sectional illustration of the semiconductor die in FIG. 5A after the solder bumps have been reflown and an IMC barrier layer is formed, according to an embodiment of the invention.

FIG. 6 is a schematic representation of a computing device that includes one or more devices with reflown solder bumps that include an IMC barrier layer, according to an embodiment of the invention.

### DETAILED DESCRIPTION OF THE INVENTION

Embodiments of the invention provide apparatuses with improved control of intermetallic compound growth in solder joints and methods of forming such apparatuses. In the following description, numerous specific details are set forth, such as specific materials and processing operations, in order to provide a thorough understanding of embodiments of the present invention. It will be apparent to one skilled in the art that embodiments of the present invention may be practiced without these specific details. In other instances, well-known features, such as the integrated circuitry of semiconductive dies, are not described in detail in order to not unnecessarily obscure embodiments of the present invention. Furthermore, it is to be understood that the various embodiments shown in the Figures are illustrative representations and are not necessarily drawn to scale.

Embodiments of the invention allow for improvements to the solder joint in the first level interconnect and solder joints used for chip to chip attachment that prevent cracking of the low-K interlayer dielectric (ILD) and stacking via on the die. Solder joints according to embodiments of the invention reduce the risk of ILD and stack via cracking by minimizing the growth of intermetallic compounds (IMCs) in the solder joint. As described above, the interface between a copper bump on the die with low-K ILD and lead-free solders (e.g., Sn based solders) results in the formation of IMCs during reflow processes. In the case of Sn-based solders, the interface between the solder and the copper bump provides a copper source that may cause the formation of Cu₆Sn₅ and Cu₃Sn IMCs. Embodiments of the invention prevent the formation of these IMCs by using a solder system that will produce a barrier layer at the interface between the solder joint and the copper bump. However, unlike the prior barrier layer solutions, such as the nickel plating layer described above, embodiments of the invention utilize the composition of the solder to selectively form an IMC that has a growth rate that is slower than the growth rate of the IMCs that would otherwise form between the tin and the copper.

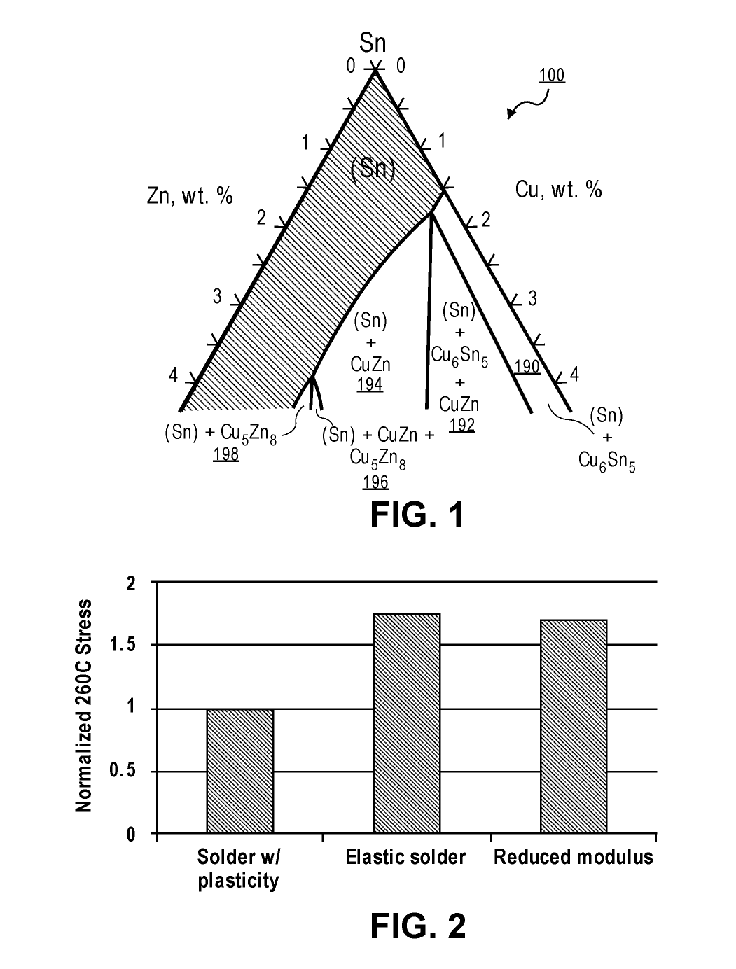

Referring now to FIG. 1, the tin corner of a tin-zinc-copper phase diagram 100 is illustrated. As shown, when soldering a high Sn based solder onto a Cu surface, the IMC that is formed in region 190 is Cu₆Sn₅. When Zn is added to the high Sn based solder (e.g., when the high Sn based solder includes approximately 0.6 weight percent Zn or more), the location on the phase diagram shifts to regions 192 and 194 where the initial IMC formed is a Cu—Zn intermetallic compound. Further, when the weight percent Zn in the high Sn based solder is increased, the location on the phase diagram shifts to regions 196 and 198 where high content Zn IMCs form, such as Cu₅Zn₈. Accordingly, the unwanted IMC compound Cu₆Sn₅ only appear when the Zn content in the molten solder is less than approximately 0.6 weight percent.

The selective formation of CuZn and Cu₅Zn₈ IMCs is beneficial because they grow significantly slower than Cu—Sn based IMCs during reflow processes. Since the IMCs grow slower, a larger proportion of the solder joint will be free from IMCs. For example, in solder joints that are approximately 25 μm thick or less, reflow processes may result in full IMC joints (i.e., solder joints where substantially the entire volume of the solder joint is formed by IMCs) in presently used solders, whereas embodiments of the present invention may include an IMC barrier layer that is less than approximately 10 μm thick. Depending on the reflow operations, the IMC barrier layer may even be less than 2 μm thick, according to certain embodiments of the invention.

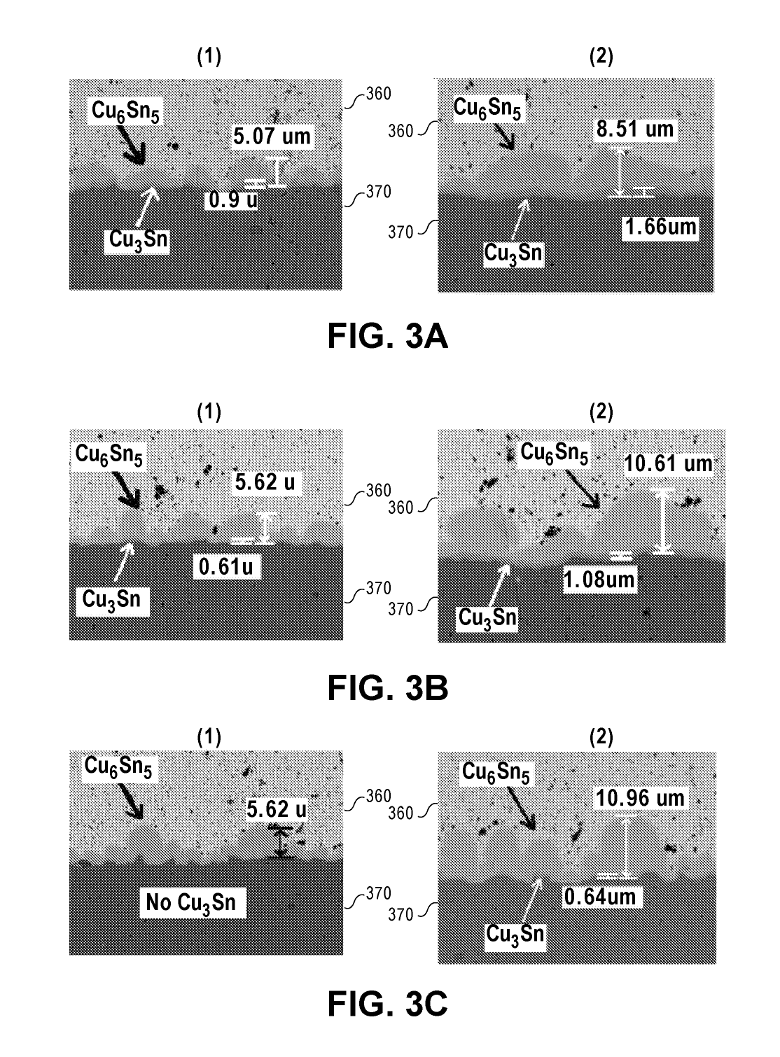

Increases in the IMC volume in the solder joint increase the stress that is applied to the ILD. FIG. 2 shows normalized values of stress on the ILD caused when the solder is reflown at 260° C. for various solder compositions. The first bar, labeled “solder with plasticity”, is considered to be a standard solder that does not include any IMCs and is, therefore, the normalized value 1. In the modeling used to create the second bar, labeled “elastic solder”, the solder composition modeled includes the same physical properties as the “solder with plasticity”, with the exception that the “elastic solder” joint does not melt at 260° C. As such, there is no plastic deformation and the solder only elastically deforms. This behavior is substantially similar to a solder joint that is fully comprised of IMCs. As illustrated, the elastic solder shows a normalized stress on the ILD that is greater than 1.5, and therefore, much more likely to cause cracking of the low K ILD. The third solder that is modeled, labeled “reduced modulus solder”, is similar to the “elastic solder” in that it does not melt and plastically deform at 260° C., but is different because it has been modeled with a modulus that is lower than the “elastic solder”. As shown, reducing the modulus also reduces the stress on the ILD compared to the “elastic solder”. Accordingly, it has been shown that even if the solder will not plastically deform, the stress on the ILD may be decreased by reducing the modulus of the solder.

While it is appreciated that including Zn into the solder will increase the hardness of the solder, it has been shown that the formation of the Zn-based IMCs at the interface will also reduce the concentration of Zn in the remaining portions of the solder. As such, the modulus of the reflown solder with Zn will not be as high as the modulus prior to reflow. Since the Zn migrates to the interface to form IMCs, the concentration of Zn in the non-IMC portions of the solder will be reduced. For example, when 0.6 weight percent Zn is added to a Sn—Cu solder or to a SAC105 solder, the solder hardness reduces after reflow. While embodiments of the invention are not bound by theory, it is presently believed that Zn in the molten solder migrates to the solder-copper interface to form the IMCs. When Cu is also included in the solder it is further believed that the Cu will also migrate to the interface. Accordingly, the reduced Zn content in the non-IMC portions of the solder joint results in a softening of the solder joints. The softer solder joints, therefore, result in less stress on the ILD.

In addition to providing a reduced hardness value by reducing the Zn composition in the non-IMC portion of the solder joint, the formation of a slow growth IMC also reduces the consumption of copper at the copper-solder interface. Reducing the copper consumption provides several benefits. One such benefit is that the thickness of the copper layer (e.g., FLI, bump, trace, etc.) can be reduced compared to current design rules. Currently, FLIs need to be approximately 10 μm thick or more to prevent cracking due to the depletion of copper during the reflow processes. According to embodiments of the invention, the formation of Zn—Cu IMCs reduces consumption of copper compared to when Sn—Cu IMCs form. As such FLIs formed according to embodiments of the invention may be less than approximately 10 μm. In some embodiments, the FLIs may be formed with a thickness that is less than approximately 2 μm. Reducing the thickness of the copper allows for the plating process used to form the FLIs to be completed faster, and results in increased throughput and reduced costs. Furthermore, reducing the copper consumption may allow for additional reflows without the risk of cracking the FLIs. For example, embodiments of the invention may include five or more reflows when the thickness of the FLI is less than approximately 2 μm. As described above, in BOT applications using currently available solders, the consumption of the trace on the substrate also causes problems such device open failures. Accordingly, embodiments of the present invention allow for the trace thickness to be reduced as well since the copper consumption is reduced. This provides similar advantages to those described above (e.g., thinner traces and the ability to withstand a greater number of reflows).

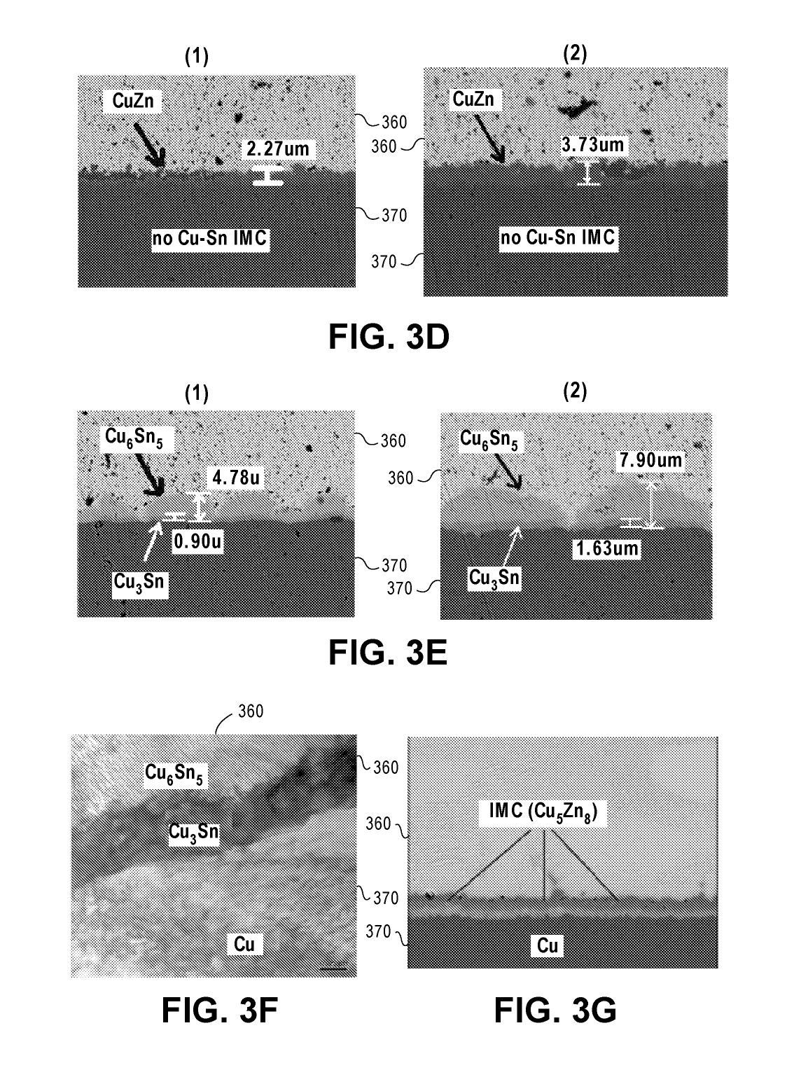

FIGS. 3A-3E are cross-sectional micrographs of the interface between various solder compositions 360 and a copper surface 370 for various solder compositions and reflow times. Each Figure illustrates two different micrographs of the same solder 360. The first micrograph is a cross-section taken after a ten minute reflow at 250° C., and the second micrograph is a cross-section taken after a thirty minute reflow at 250° C. Accordingly, each Figure illustrates the IMC compounds that are formed and the relative speed at which each IMC compound grows. It is to be appreciated that the micrographs shown in FIG. 3A-3E are exemplary in nature and provide a general illustration of the effect of Zn concentration in a Sn-based solder on the growth of intermetallic compounds. The reflow temperatures, the reflow times, the compositions, and the resulting thicknesses of the IMC layers are exemplary in nature, and embodiments of the invention are not limited to such configurations.

FIG. 3A is a cross-sectional micrograph of an interface between a Sn100 solder 360 and copper 370. As illustrated in the first micrograph of FIG. 3A, Cu₆Sn₅ and Cu₃Sn IMCs have formed. The maximum thickness of the Cu₆Sn₅ IMC extends approximately 5.07 μm into the solder 360 and the thickness of the Cu₃Sn IMC extends approximately 0.90 μm into the solder 360. As shown, the Cu₃Sn IMC has a thickness that is substantially consistent and is located at the interface between the solder 360 and the copper 370, whereas the Cu₆Sn₅ IMC has a greater degree of variation in the thickness and is formed above the Cu₃Sn IMC. The Cu₆Sn₅ IMC has a greater variation in its thickness because the IMC forms peaks and valleys of varying thickness.

As illustrated in the second micrograph of FIG. 3A, the maximum thickness of the Cu₆Sn₅ IMC has extended approximately 8.51 μm into the solder 360 after the thirty minute reflow, and the thickness of the Cu₃Sn IMC has extended approximately 1.66 μm into the solder system. The Cu₃Sn IMC maintains a relatively consistent thickness at the interface, and the peaks and valleys in the Cu₆Sn₅ IMC regions have begun to merge together. Accordingly, while the copper heavy IMC Cu₃Sn forms preferentially at the interface, it does not act as a barrier that prevents the IMC from continuing to form deeper into the solder system.

Referring now to FIG. 3B, a cross-sectional micrograph of an interface between a solder 360 that is Sn with 0.2 weight percent Zn is shown. As illustrated in the first micrograph of FIG. 3B, Cu₆Sn₅ and Cu₃Sn IMCs have formed. The maximum thickness of the Cu₆Sn₅ IMC extends approximately 5.62 μm into the solder 360 and the thickness of the Cu₃Sn IMC extends approximately 0.61 μm into the solder 360. As shown, the Cu₃Sn IMC has a thickness that is substantially consistent and is located at the interface between the solder 360 and the copper 370, whereas the Cu₆Sn₅ IMC has a greater degree of variation in the thickness and is formed above the Cu₃Sn IMC. The Cu₆Sn₅ IMC has a greater variation in its thickness because the IMC forms peaks and valleys of varying thickness.

As illustrated in the second micrograph of FIG. 3B, the maximum thickness of the Cu₆Sn₅ IMC has extended approximately 10.61 μm into the solder 360 after the thirty minute reflow, and the thickness of the Cu₃Sn IMC has extended approximately 1.08 μm into the solder system. The Cu₃Sn IMC maintains a relatively consistent thickness at the interface, and the peaks and valleys in the Cu₆Sn₅ IMC regions have begun to merge together. Accordingly, while the copper heavy IMC Cu₃Sn forms preferentially at the interface, it does not act as a barrier that prevents the IMC from continuing to form deeper into the solder system.

Referring now to FIG. 3C, a cross-sectional micrograph of an interface between a solder 360 that is Sn with 0.6 weight percent Zn is shown. As illustrated in the first micrograph of FIG. 3C, Cu₆Sn₅ IMCs have formed. The maximum thickness of the Cu₆Sn₅ IMC extends approximately 5.92 μm into the solder 360. As shown, the Cu₆Sn₅ IMC has variation in its thickness because the IMC forms peaks and valleys of varying thickness. Further, unlike the first micrographs in FIGS. 3A and 3B, the interface does not include a Cu₃Sn IMC layer.

As illustrated in the second micrograph of FIG. 3C, the maximum thickness of the Cu₆Sn₅ IMC has extended approximately 10.96 μm into the solder 360 after the thirty minute reflow. Additionally, the extended reflow time has produced a Cu₃Sn IMC layer that is approximately 0.64 μm thick. The Cu₃Sn IMC layer has a substantially consistent thickness and is formed directly on the interface between the solder 360 and the copper 370. Similar to the previous figures the peaks and valleys of the Cu₆Sn₅ IMC layer have begun to merge together after the thirty minute reflow.

Referring now to FIG. 3D, a cross-sectional micrograph of an interface between a solder 360 that is Sn with 2.0 weight percent Zn is shown. As illustrated in the first micrograph of FIG. 3D, CuZn IMCs have formed. The thickness of the CuZn IMC extends approximately 2.27 μm into the solder 360. The thickness of the CuZn IMC layer is substantially consistent across the interface.

As illustrated in the second micrograph of FIG. 3D, the thickness of the CuZn IMC has extended approximately 3.73 μm into the solder 360 after the thirty minute reflow. The thickness of the CuZn IMC remains substantially consistent across the interface after the thirty minute reflow. Accordingly, the presence of 2.0 weight percent Zn in the solder 360 allows for a barrier layer of CuZn to form preferentially at the interface between the copper 370 and the solder 360. Furthermore, the barrier layer of CuZn blocks the formation of Sn-based IMCs in the remainder of the reflown solder 360. Since the CuZn IMC does not grow as fast as the Cu₆Sn₅ IMC, the thickness of the IMCs is also decreased relative to other solder compositions that have less than approximately 0.6 weight percent Zn.

Referring now to FIG. 3E, a cross-sectional micrograph of an interface between a solder 360 that is Sn with 0.7 weight percent Cu is shown. As illustrated in the first micrograph of FIG. 3E, Cu₆Sn₅ and Cu₃Sn IMCs have formed. The maximum thickness of the Cu₆Sn₅ IMC extends approximately 4.78 μm into the solder 360 and the thickness of the Cu₃Sn IMC extends approximately 0.90 μm into the solder 360. As shown, the Cu₃Sn IMC has a thickness that is substantially consistent and is located at the interface between the solder 360 and the copper 370, whereas the Cu₆Sn₅ IMC has a greater degree of variation in the thickness and is formed above the Cu₃Sn IMC. The Cu₆Sn₅ IMC has a greater variation in its thickness because the IMC forms peaks and valleys of varying thickness.

As illustrated in the second micrograph of FIG. 3E, the maximum thickness of the Cu₆Sn₅ IMC has extended approximately 7.90 μm into the solder 360 after the thirty minute reflow, and the thickness of the Cu₃Sn IMC has extended approximately 1.63 μm into the solder system. The Cu₃Sn IMC maintains a relatively consistent thickness at the interface, and the peaks and valleys in the Cu₆Sn₅ IMC regions have begun to merge together. Accordingly, while the copper heavy IMC Cu₃Sn forms preferentially at the interface, it does not act as a barrier that prevents the IMC from continuing to form deeper into the solder system.

Referring now to FIG. 3F, an additional micrograph of the interface between a solder composition 360 and copper 370 is shown. In FIG. 3F, the solder composition is a SAC solder with 0.4 weight percent Zn. As illustrated, the addition of 0.4 weight percent Zn to the SAC solder does not prevent the formation of a Cu₃Sn IMC at the interface, or the growth of a Cu₆Sn₅ IMC above the Cu₃Sn IMC layer.

Referring now to FIG. 3G, an additional micrograph of the interface between a solder composition 360 and copper 370 is shown. In FIG. 3G, the solder composition is a SAC solder with 1.5 weight percent Zn. As illustrated, the addition of 1.5 weight percent Zn to the SAC solder does eliminate the growth of the Cu—Sn IMC layers. Instead, a thing Cu₅Zn₈ IMC layer is formed directly on the interface between the copper 370 and the solder 360.

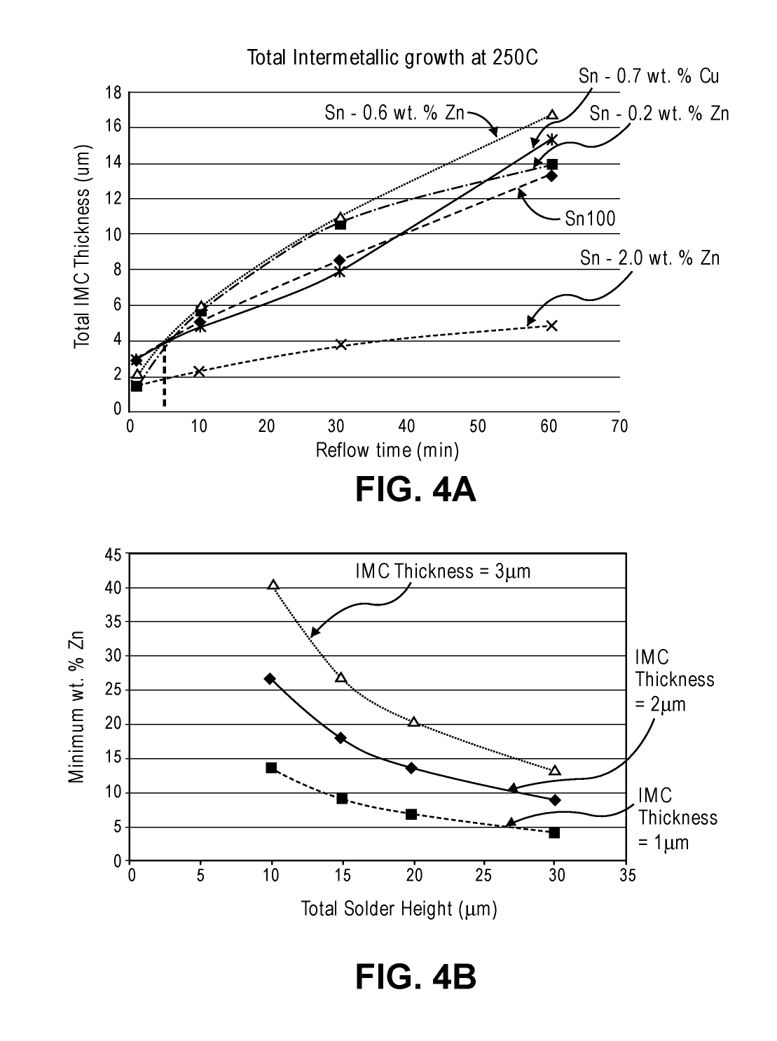

Referring now to FIG. 4A, a graph of the total intermetallic growth in reflown solder systems in contact with a copper surface over various reflow times at 250° C. are illustrated. As illustrated, at reflow times below approximately five minutes, the solder systems that include some amount of Zn (e.g., Sn with 0.2 weight percent Zn, Sn with 0.6 weight percent Zn, and Sn with 2.0 weight percent Zn) have the smallest thicknesses of IMC growth. Furthermore, the IMC growth of Sn with 2.0 weight percent Zn continues to have the smallest thickness of IMC growth throughout all times of the reflow. Accordingly, experimental evidence show that Sn with 2.0 weight percent Zn successfully suppresses the interfacial IMC growth, whereas solders compositions that have less than approximately 0.6 weight percent Zn are not able to suppress the interfacial IMC growth. This experimental evidence in conjunction with the phase diagram in FIG. 1 illustrates that when a Sn solder has a Zn weight percentage that is approximately greater than 0.6 weight percent, the unwanted Sn—Cu IMCs are suppressed, and the slower growing Zn—Cu IMCs are preferentially formed. Accordingly, embodiments of the invention allow for the formation of a relatively thin IMC barrier layer that prevents the spread of IMCs through the entire solder joint.

According to an embodiment of the invention, the Sn solder may include approximately 2 weight percent Zn or greater. Additionally, doping elements (e.g., Al, Ag, Au, Cu, etc.) may be included in the solder as well. For example, the solder may have a composition Sn—Xwt % Zn—Y, where X is between 2 and 10 and Y is a doping element (e.g., Al, Ag, Au, Cu, etc.). Embodiments of the invention may alter the weight percentage of Zn in order to provide a sufficient amount of Zn at the solder-copper interface.

Referring now to FIG. 4B, a plot of the minimum Zn weight percent needed in a solder to provide a Cu—Zn IMC at both joint interfaces is shown according to an embodiment of the invention. As used herein, the total solder height (shown along the x-axis) refers to the height of the solder plated on a Cu bump plus the height of the solder on the substrate. According to an embodiment, Cu—Zn solder can be plated on a Cu bump, followed by soldering onto a Cu trace on the substrate. Additional embodiments may include adding Cu—Zn solder onto substrate Cu trace. In either embodiment, the total solder height is the height of the solder on the Cu bump plus the height of the solder on the substrate.

In FIG. 4B, the data points marked by squares represent the formation of a 1 μm thick Cu—Zn IMC, the data points marked by diamonds represent the formation of a 2 μm thick Cu—Zn IMC, and the data points marked by triangles represent the formation of a 3 μm thick Cu—Zn IMC. According to an embodiment, such IMC thicknesses are representative of the IMC thickness obtained at end of line of assembly (e.g., 1-2 μm) and after two to four reflows following chip attachment (e.g., 2-3 μm) and after temperature cycling testing (e.g., about 3 μm). As illustrated, the total solder height influences the minimum concentration of Zn. For example, the solder joints with relatively high total solder heights require a lower minimum Zn concentration. A lower minimum Zn concentration is needed because more Zn is available away from the interface due to the increased volume of solder. The Zn that is located away from the interface may migrate towards the interface during a reflow in order to form Zn—Cu IMCs.

In embodiments where the Cu pad size on the substrate is the same as the Cu bump diameter, then the minimum Zn concentration needed in the solder is not dependent on the Cu bump diameter or Cu pad size on the substrate. However, in embodiments that include different sizes for the Cu bump and the Cu pad size on the substrate, then the true soldering surface will affect the minimum weight percentage of Zn that is needed. For example, increasing the surface area of the interface requires more Zn to be available to interact with the copper to form the Zn—Cu IMCs. As such, a higher concentration of Zn is needed when the surface area of the interface is increased.

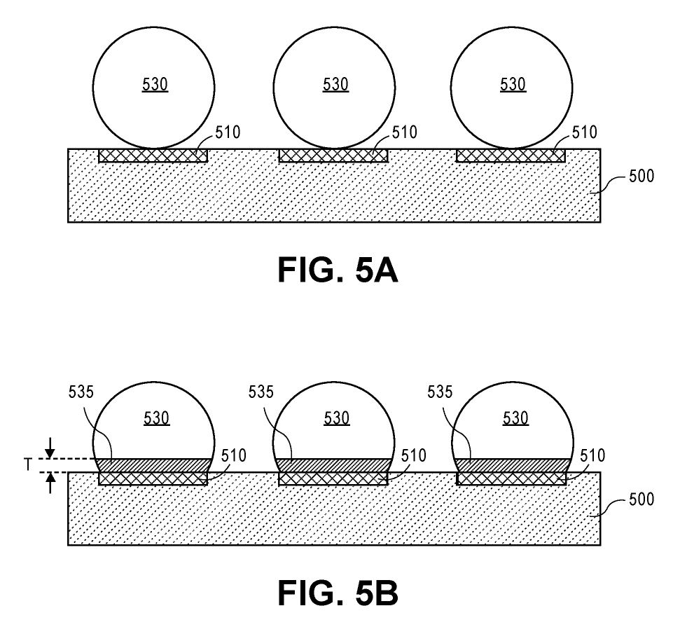

Referring now to the cross-sectional illustrations in FIGS. 5A and 5B, a reflow process of a solder joint formed in accordance with an embodiment of the invention is illustrated. In FIG. 5A, a semiconductor die 500 is illustrated. The semiconductor die 500 may include one or more die contacts 510. The die contacts 510 may be formed in the back end of line (BEOL) stack that includes one or more ILD layers, conductive traces, vias, and solder resist (not shown) in order to provide first level interconnects (FLI) to device circuitry (not shown) in the semiconductor die 500. The die contacts 510 may be a stack of one or more conductive materials and may include an organic surface protectant (OSP). In one embodiment, the top surfaces of the die contacts 510 are copper.

As illustrated in FIG. 5A, unreflown solder bumps 530 may be placed on one or more of the die contacts 510. By way of example, and not by way of limitation, the solder bumps 530 may be formed on the die contacts with a plating process, a solder ball attachment process, a paste printing process, or the like. According to an embodiment, the solder bumps 530 are a solder composition that includes a barrier forming element. As used herein, a barrier forming element is an element that induces formation of a slow-growing IMC layer at the interface between the die contact 510 and the solder bump 530 during one or more reflow operations.

Embodiments of the invention may include solder compositions, such as a Sn-based solder, an Ag-based solder, a SAC solder, or the like. In such embodiments, the barrier forming element may be Zn. For example, the solder bumps 530 may be a Sn-based solder that includes approximately 0.6 weight percent or greater of Zn. In an additional embodiment, the weight percent of the Zn in a Sn-based solder may be between approximately 0.6 weight percent Zn and 5.0 weight percent Zn. In another embodiment, the weight percent of the Zn in a Sn-based solder may be between approximately 1.0 weight percent Zn and 10.0 weight percent Zn.

Embodiments of the invention may include determining the weight percentage of Zn to be added to the solder based on the thickness of the solder joint and/or the surface area of the die contact 510. Since the Zn is needed to form the barrier layer at the interface, there needs to be a sufficient weight percentage of Zn in the solder to form the barrier layer over the entire surface of the interface. For example, if a relatively thin solder joint is formed over a relatively large surface area, then a greater weight percentage of Zn would be needed compared to a relatively thick solder joint formed over a relatively small surface area. In the latter case, even though a lower weight percentage of Zn may be used, the increased volume of the solder would provide sufficient Zn atoms to form the desired Zn-based IMC barrier layer. Furthermore, since the surface area of the interface is smaller, fewer Zn atoms are needed to form the barrier layer. Therefore, the weight percentage of Zn in the solder may be reduced. In an embodiment, the weight percentage of Zn in a solder may be no greater than the weight percentage needed to prevent the formation of Cu₆Sn₅ IMCs in the solder joint during one or more reflow operations. Accordingly, embodiments of the invention allow for maximum protection from unwanted IMC growth without significantly increasing the hardness of the solder joint.

Referring now to FIG. 5B, the solder bumps 530 are reflown. According to an embodiment, the reflow process produces an IMC barrier layer 535 at the interface between the solder bump 530 and the die contact 510. In an embodiment the IMC barrier layer 535 is a Zn—Cu IMC. For example, the IMC barrier layer 535 may include CuZn and/or Cu₅Zn₈ IMCs. As described above, the formation of the IMC barrier layer 535 substantially prevents the formation of rapid growing Sn—Cu IMCs. In an embodiment, the IMC barrier layer 535 may extend into the solder joint a thickness T that is less than approximately 25 μm. Embodiments may also include an IMC barrier layer 535 that extends into the solder joint a thickness T that is less than approximately 10 μm. Embodiments may also include an IMC barrier layer 535 that extends into the solder joint a thickness T that is less than approximately 6 μm. Accordingly, the remainder of the solder bump 530 is substantially free from IMC growth. The IMC free portion of the solder bump results in reduced stress on the ILD of the semiconductor die 510 and, therefore reduces the probability that the ILD will crack during reflow operations.

Furthermore, the reduced thickness of the IMC barrier layer 535 compared to prior solder compositions, allows for thinner solder joints. For example, solder joints less than 15 μm are possible. The thickness of the solder joint may be limited by factors such as solder resist thickness, the need to reduce warpage of the package and dies during reflow (e.g., oven reflow), or the like. The ability to minimize solder joint thickness without producing solder joints that are completely comprised of IMCs, according to embodiments of the invention, therefore, allows for the thickness of the solder joints to continue to be scaled down.

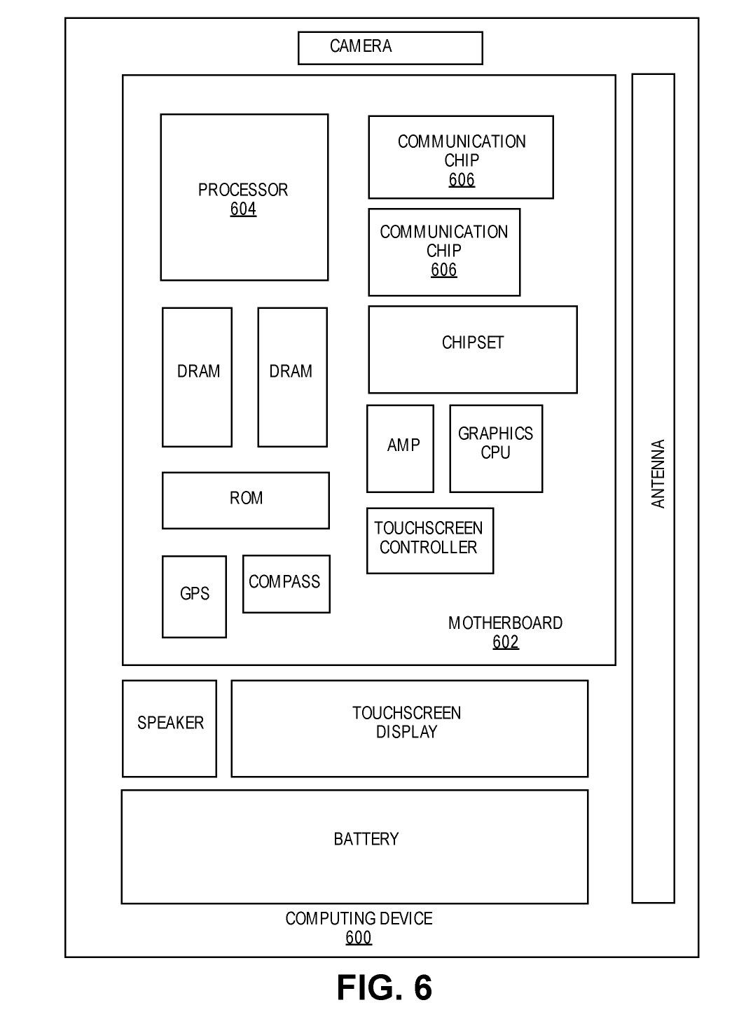

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor includes one or more devices, such as devices that include a first level interconnect that include a barrier layer of Zn-based IMCs in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip includes one or more devices, such as devices that include a first level interconnect that include a barrier layer of Zn-based IMCs in accordance with implementations of the invention.

Embodiments of the invention include a semiconductor device that comprises; a semiconductor die with one or more die contacts; and a reflown solder bump on one or more of the die contacts, wherein an intermetallic compound (IMC) barrier layer is formed at the interface between the solder bump and the die contact.

An additional embodiment of the invention comprises a semiconductor device, wherein the reflown solder bump includes a weight percentage of Zn that is approximately 0.6 weight percent or greater.

An additional embodiment of the invention comprises a semiconductor device, wherein the weight percentage of Zn is approximately 2.0 weight percent or greater.

An additional embodiment of the invention comprises a semiconductor device, wherein the weight percentage of Zn is between approximately 0.6 weight percent and 5.0 weight percent.

An additional embodiment of the invention comprises a semiconductor device, wherein the IMC barrier layer includes CuZn.

An additional embodiment of the invention comprises a semiconductor device, wherein the IMC barrier layer includes Cu₅Zn₈.

An additional embodiment of the invention comprises a semiconductor device, wherein the IMC barrier layer is less than approximately 10 μm thick.

An additional embodiment of the invention comprises a semiconductor device, wherein the IMC barrier layer is less than approximately 6 μm thick.

An additional embodiment of the invention comprises a semiconductor device, wherein the die contacts are copper.

An additional embodiment of the invention comprises a semiconductor device, wherein an organic surface protectant (OSP) is formed over the die contacts.

An additional embodiment of the invention comprises a semiconductor device, wherein the die contacts are less than 5 μm thick.

An additional embodiment of the invention comprises a semiconductor device, wherein the die contacts are less than 2 μm thick.

An additional embodiment of the invention comprises a semiconductor device, wherein the die contacts are less than 2 μm thick.

An additional embodiment of the invention comprises a semiconductor device, wherein the solder bumps are first level interconnects.

Embodiments of the invention include a method of forming a solder interconnect, comprising: forming a die contact on a semiconductor die; forming a solder bump on the die contact, wherein the solder bump is a Sn-based solder that includes a barrier forming element; and reflowing the solder, wherein the barrier forming element reacts with the die contact to form an intermetallic compound (IMC) barrier layer.

Additional embodiments of the invention include a method, wherein the barrier forming element is Zn and the die contact includes Cu.

Additional embodiments of the invention include a method, wherein the IMC barrier layer includes CuZn and/or Cu₅Zn₈.

Additional embodiments of the invention include a method, wherein the solder bump includes a composition of between approximately 2 weight percent Zn and 10 weight percent Zn.

Additional embodiments of the invention include a method, wherein the solder bump further comprises one or more of Al, Au, Ag, and Cu.

Additional embodiments of the invention include a method, wherein reflowing the solder bump includes a plurality of reflows.

Additional embodiments of the invention include a method, wherein reflowing the solder bump includes five or more reflows.

Additional embodiments of the invention include a method, wherein the IMC barrier layer is less than approximately 10 μm thick.

Additional embodiments of the invention include a method, wherein forming the die contact includes forming the die contact to a thickness less than approximately 5.0 μm.

Embodiments of the invention include a semiconductor device, comprising: a semiconductor die with one or more die contacts, wherein the one or more die contacts are less than approximately 5 μm thick and include copper; and a reflown solder bump on one or more of the die contacts, wherein the reflown solder bump is a Sn-based solder that includes between approximately 2 weight percent Zn and 10 weight percent Zn, and wherein a portion of the Zn reacts with the copper from the die contact to form an intermetallic compound (IMC) barrier layer comprising CuZn and/or Cu₅Zn₈ at the interface between the reflown solder bump and the die contact.

Additional embodiments include a semiconductor device, wherein the IMC barrier layer is less than 10 μm thick and the reflown solder bump is less than 25 μm thick.

Additional embodiments include a semiconductor device, wherein the reflown solder bump further comprises one or more of Al, Au, Ag, and Cu.

What is claimed is:

1. A semiconductor device, comprising:
a semiconductor die with one or more die contacts; and
a reflown solder bump on one or more of the die contacts, wherein an intermetallic compound (IMC) barrier layer is formed at the interface between the solder bump and the die contact.

2. The semiconductor device of claim 1, wherein the reflown solder bump includes a weight percentage of Zn that is approximately 0.6 weight percent or greater.

3. The semiconductor device of claim 2, wherein the weight percentage of Zn is between approximately 0.6 weight percent and 5.0 weight percent.

4. The semiconductor device of claim 2, wherein the weight percentage of Zn is approximately 2.0 weight percent or greater.

5. The semiconductor device of claim 1, wherein the IMC barrier layer includes CuZn.

6. The semiconductor device of claim 1, wherein the IMC barrier layer includes Cu₅Zn₈.

7. The semiconductor device of claim 1, wherein the IMC barrier layer is less than approximately 10 μm thick.

8. The semiconductor device of claim 7, wherein the IMC barrier layer is less than approximately 6 μm thick.

9. The semiconductor device of claim 1, wherein the die contacts are copper.

10. The semiconductor device of claim 9, wherein an organic surface protectant (OSP) is formed over the die contacts.

11. The semiconductor device of claim 10, wherein the die contacts are less than 5 μm thick.

12. The semiconductor device of claim 11, wherein the die contacts are less than 2 μm thick.

13. The semiconductor device of claim 1, wherein the solder bumps are first level interconnects.

14. A method of forming a solder interconnect, comprising:
forming a die contact on a semiconductor die;
forming a solder bump on the die contact, wherein the solder bump is a Sn-based solder that includes a barrier forming element; and
reflowing the solder, wherein the barrier forming element reacts with the die contact to form an intermetallic compound (IMC) barrier layer.

15. The method of claim 14, wherein the barrier forming element is Zn and the die contact includes Cu.

16. The method of claim 15, wherein the IMC barrier layer includes CuZn and/or Cu₅Zn₈.

17. The method of claim 16, wherein the solder bump includes a composition of between approximately 2 weight percent Zn and 10 weight percent Zn.

18. The method of claim 17, wherein the solder bump further comprises one or more of Al, Au, Ag, and Cu.

19. The method of claim 14, wherein reflowing the solder bump includes a plurality of reflows.

20. The method of claim 19, wherein reflowing the solder bump includes five or more reflows.

21. The method of claim 14, wherein the IMC barrier layer is less than approximately 10 μm thick.

22. The method of claim 14, wherein forming the die contact includes forming the die contact to a thickness less than approximately 5.0 μm.

23. A semiconductor device, comprising:
a semiconductor die with one or more die contacts, wherein the one or more die contacts are less than approximately 5 μm thick and include copper; and
a reflown solder bump on one or more of the die contacts, wherein the reflown solder bump is a Sn-based solder that includes between approximately 2 weight percent Zn and 10 weight percent Zn, and wherein a portion of the Zn reacts with the copper from the die contact to form an intermetallic compound (IMC) barrier layer comprising CuZn and/or Cu₅Zn₈ at the interface between the reflown solder bump and the die contact.

24. The semiconductor device of claim 23, wherein the IMC barrier layer is less than 10 μm thick and the reflown solder bump is less than 25 μm thick.

25. The semiconductor device of claim 23, wherein the reflown solder bump further comprises one or more of Al, Au, Ag, and Cu.
